(19) United States
(12) Patent Application Publication
(10) Pub. No.: US 2012/0125391 A1
(43) Pub. Date: May 24, 2012

(54) METHODS FOR INTERCONNECTING PHOTOVOLTAIC CELLS

(75) Inventors: Mustafa Pinarbasi, Morgan Hill, CA (US); Eric Lee, San Jose, CA (US); Serkan Erdemli, San Jose, CA (US); Eugene Petrushansky, Fremont, CA (US)

(73) Assignee: SoloPower, Inc., San Jose, CA (US)

(21) Appl. No.: 12/950,831

(22) Filed: Nov. 19, 2010

(51) Int. Cl. H01L 31/05; H01L 31/18

(52) U.S. Cl. 136/244; 438/67; 257/E31.11

(57) ABSTRACT

Two or more solar cells are shingled together. At least one solar cell has a contact formed on a first surface that is electrically connected to the conductive terminal of the solar cell. A substrate of a second cell is physically and electrically coupled to the contact. An insulator is interposed between the substrate of the second cell and the first cell to inhibit short circuits therebetween.

### BACKGROUND

1. Field of the Inventions

The present inventions generally relate to apparatus and methods of solar module design and fabrication and, more particularly, to interconnecting solar cells.

2. Description of the Related Art

Solar cells are photovoltaic (PV) devices that convert sunlight directly into electrical energy. Solar cells can be based on crystalline silicon or thin films of various semiconductor materials that are usually deposited on low-cost substrates, such as glass, plastic, or stainless steel.

Thin film based photovoltaic cells, such as amorphous silicon, cadmium telluride, copper indium diselenide or copper indium gallium diselenide based solar cells, offer improved cost advantages by employing deposition techniques widely used in the thin film industry. Group IBIIIAVIA compound photovoltaic cells, including copper indium gallium diselenide (CIGS) based solar cells, have demonstrated the greatest potential for high performance, high efficiency, and low cost thin film PV products.

A conventional Group IBIIIAVIA compound solar cell can be built on a substrate including a sheet of glass, a sheet of metal, an insulating foil or web, or a conductive foil or web. A contact layer such as a molybdenum (Mo) film is coated on the substrate as the back electrode of the solar cell. An absorber thin film including a material in the family of Cu(In,Ga)(S,Se)₂, is formed on the conductive Mo film. After the absorber film is formed, a transparent layer, for example, a CdS film, a ZnO film or a CdS/ZnO film-stack, is formed on the absorber film. The preferred electrical type of the absorber film is p-type, and the preferred electrical type of the transparent layer is n-type. However, an n-type absorber and a p-type window layer can also be formed. The above described conventional device structure is called a substrate-type structure. In the substrate-type structure light enters the device from the transparent layer side. A so called superstrate-type structure can also be formed by depositing a transparent conductive layer on a transparent superstrate, such as glass or transparent polymeric foil, and then depositing the Cu(In,Ga)(S,Se)₂ absorber film, and finally forming an ohmic contact to the device by a conductive layer. In the superstrate-type structure light enters the device from the transparent superstrate side.

In standard CIGS as well as Si and amorphous Si module technologies, the solar cells are preferably manufactured on conductive substrates such as aluminum or stainless steel foils. In such solar cells, the transparent layer and the conductive substrate form the opposite poles of the solar cell. Multiple solar cells can be electrically interconnected by stringing or shingling methods that establish electrical connection between the opposite poles of the solar cells. Such interconnected solar cells are then packaged in protective packages to form solar modules or panels. Many modules can also be combined to form large solar panels. The solar modules are constructed using various packaging materials to mechanically support and protect the solar cells in them against mechanical damage. Each module typically includes multiple solar cells which are electrically connected to one another using above mentioned stringing or shingling interconnection methods.

FIG. 1A shows an exemplary substrate-type solar cell 10A in top view. Light depicted by arrows ‘L’ enters the solar cell 10A through the top transparent layer 13. A conductive grid 14 including conductive fingers 16 connected to a busbar 18 are formed over the transparent layer 13 to collect the current produced by the device. In stringing, the solar cells are interconnected in series using conductive leads between the solar cells. The conductive leads electrically connect the conductive grid of a preceding solar cell to the substrate of a following solar cell in series. However, the substrate of the following cell is directly connected to the conductive grid of the preceding cell when a number of solar cells are serially interconnected using the shingling method. FIG. 1B shows the exemplary solar cell 10A interconnected to another solar cell 10B by the shingling interconnection method. In addition to the top transparent layer 13 and the conductive grid 14 shown in FIG. 1A, each solar cell also includes a conductive substrate 11 and an absorber layer 12 as the essential components. The preferred electrical type of the absorber layer 12 is p-type, and the preferred electrical type of the transparent layer 13 is n-type. However, an n-type absorber and a p-type transparent layer can also be formed.

Shingling can be done by overlapping a cell onto another cell and making an electrical connection between the opposite poles of the cells to form a series connection. As shown in FIG. 1B, to shingle interconnect these two solar cells, the conductive grid 14 of the solar cell 10A can be attached to the substrate of the solar cell 10B using a conductive adhesive 20, thereby making electrical connection between the opposite poles of the solar cells.

However, without any dielectric material protection between the cells, various components of the interconnected cells may touch one another resulting in greater potential of shorting in the interconnected circuit. This is, for example, a particular problem in flexible solar modules using thin film solar cells as the substrate of the upper solar cell can penetrate into the absorber layer and contact the substrate of the bottom solar cell when the flexible module is placed under stress due to bending.

From the foregoing, there is a need in the solar cell industry, especially in thin film photovoltaics, for better interconnection techniques that minimize shorting between the interconnected solar cells.

### SUMMARY

These and other aspects and advantages are described further herein.

The aforementioned needs are satisfied by the present invention which, in one implementation comprises a method of serially interconnecting first and second solar cells in a shingled manner, wherein each solar cell includes an absorber layer interposed between a conductive substrate and a transparent layer having a top surface on which a conductive terminal including conductive fingers connected to a current collecting busbar is disposed. In this implementation, the method comprises forming at least one contact on the current collecting busbar disposed over an edge portion of the first solar cell; disposing an electrically insulating layer over the current collecting busbar and at least a portion of the top surface of the transparent layer, the electrically insulating layer at least partially exposing the at least one contact. In this implementation, the method further comprises arranging the first and second cells in a shingled relationship so as to connect a selected area of a portion of the conductive substrate of the second solar cell to the at least one contact on the conductive terminal of the first solar cell to establish continuous electrical connection between the terminal of the first solar cell and the substrate of the second solar cell while the portion of the conductive substrate of the second cell is resting on the electrically insulating layer that is at least partially exposing the at least one contact to inhibit short circuits between the conductive substrate of the second solar cell and the edge portion of the first solar cell.

In another implementation the present invention comprises a solar cell assembly which comprises a first solar cell which includes a conductive substrate and a transparent layer with an absorber layer interposed therebetween, wherein the transparent layer defines an upper surface and wherein a conductive terminal is formed on the upper surface of the transparent layer. The assembly further comprises at least one contact formed so as to be electrically connected to the conductive terminal of the first solar cell and an insulator that is positioned on the upper surface of the first solar cell, wherein the insulator defines an opening that provides access to the at least one contact. The assembly, in this implementation, further comprises a second solar cell which includes a conductive substrate wherein the second solar cell is positioned so that the conductive substrate is positioned over the opening in the insulator in the first solar cell so that the conductive substrate of the second solar cell is in physical and electrical contact with the at least one contact and wherein the insulator provides electrical insulation between the conductive substrate of the second solar cell and the first solar cell to inhibit short circuits therebetween.

### BRIEF DESCRIPTION OF THE DRAWINGS

FIG. 1A is a schematic view a solar cell in top view;

FIG. 1B is a schematic side view of solar cells interconnected using a conventional shingling technique;

FIGS. 2A-2B are schematic side and top views of a solar cell;

FIGS. 3A-3C are schematic views of various insulation layers used with the shingling technique of at least one embodiment of the present invention;

FIG. 4A is a schematic perspective view of two solar cells aligned to be interconnected according to at least one embodiment of the present invention;

FIG. 4B is a schematic partial side view of the solar cells shown in FIG. 4A;

FIG. 4C is a schematic partial side view of the solar cells shown in FIG. 4B after the interconnection is completed wherein the interconnection between the solar cells has been provide by an insulated conductive layer;

FIG. 5A is a schematic perspective view of two solar cells aligned to be interconnected using an insulated conductive foil according to another embodiment of the present invention;

FIGS. 5B-5C are schematic detail views of the front side and back side of the conductive foil shown in FIG. 5A; and

FIG. 5D is a schematic partial side view of the solar cells shown in FIG. 5A after the interconnection is completed wherein the interconnection between the solar cells has been provided by the insulated conductive foil.

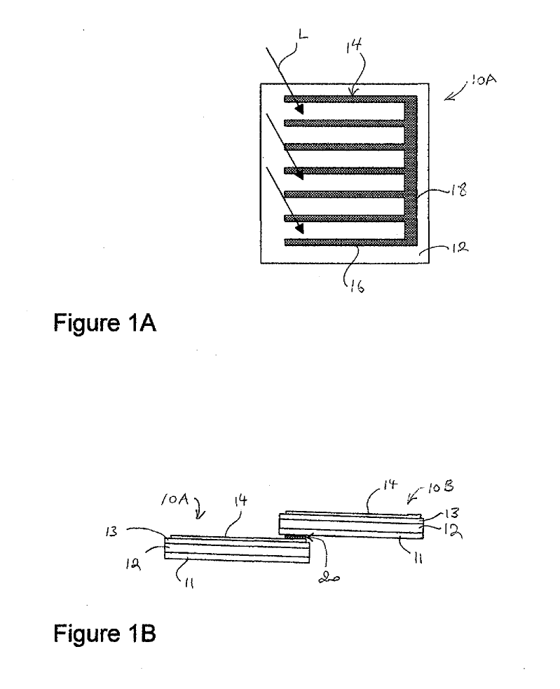

### DETAILED DESCRIPTION OF THE PREFERRED EMBODIMENTS

The preferred embodiments described herein provide methods of interconnecting solar cells or photovoltaic cells. In one embodiment, the solar cells, for example a first and second solar cells, may be interconnected in series in a manner referred to as a shingled relationship such that a substrate portion of the second solar cell overlaps with a surface portion of the first solar cell.

In one embodiment, each interconnected solar cell includes a thin film absorber layer interposed between a conductive substrate and a transparent layer, the thin film absorber layer having a top surface on which a conductive terminal including conductive fingers connected to a current collecting busbar is disposed. The solar cells may be interconnected using a contact formed on the current collecting busbar that is located at an edge portion of the first solar cell. An insulation layer may be disposed over the terminal and the top surface of the transparent layer of the first solar cell. The insulation layer may have at least one opening exposing at least a portion of the contact. The insulation layer may at least partially cover the terminal and top surface. However, in another embodiment, an insulation layer including at least one opening exposing at least a portion of the current collection busbar may be first deposited over the first solar cell.

In one implementation, the first and the second solar cells are disposed in a shingled relationship to connect a selected area of a portion of the conductive substrate of the second solar cell to a contact on the current collecting busbar of the first solar cell, thereby establishing a continuous electrical connection between the terminal of the first solar cell and the substrate of the second solar cell. When the solar cells are connected, the portion of the conductive substrate of the second cell rests on the electrically insulating layer without touching any other parts of the first solar cell to inhibit short circuits between the conductive substrate of the second solar cell and the exposed components at the edge portion of the first solar cell. The interconnection method using the insulated contacts establishes a continuous current path between the interconnected solar cells with less danger of shorting between the cells and thereby increasing the reliability of the modules manufactured thereby while simplifying the manufacturing process.

The preferred embodiments will be described with reference to specific, series interconnected solar cell configurations or arrays. However, it will be appreciated that embodiments of the present invention may be practiced with other configurations including parallel interconnected and series-parallel interconnected solar cell configurations. The embodiments will be described using an interconnection process for preferably thin film CIGS solar cells formed on flexible metallic foil substrates, however, variations of the type of solar cell may also be used without departing from the scope of the present invention.

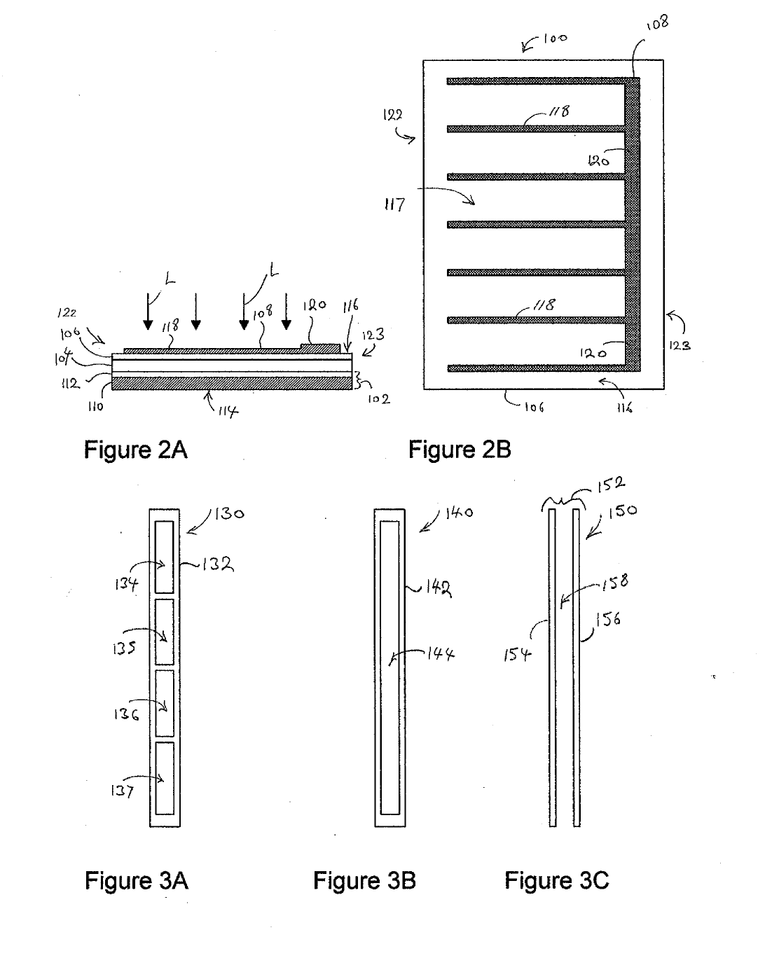

FIGS. 2A and 2B show an exemplary thin film solar cell 100 in side view and top view respectively. The solar cell 100 comprises the following components: a base 102; an absorber layer 104 formed over the base; a transparent layer 106 formed over the absorber layer 104; and a conductive terminal 108 formed on the transparent layer. The base 102 may be a conductive base including a substrate 110 and a contact layer 112 deposited on the substrate. A back surface 114 of the substrate is exposed and at least a portion of the back surface may be used interconnecting the solar cell 100 to other solar cells. For this embodiment, a preferred substrate material may be a flexible metallic material such as a stainless steel foil, an aluminum (Al) foil or the like. An exemplary material for the contact layer 112 may be molybdenum (Mo). The absorber layer 104 may be a Group IBIIIAVIA compound semiconductor such as Cu(In,Ga)(S,Se)₂ or as often referred to as CIGS absorber layer. The transparent layer 106 may be a buffer-layer/TCO (transparent conductive oxide) stack, formed on the absorber layer 104. An exemplary buffer material may be a (Cd,Zn)S which is deposited on the absorber layer. The TCO layer is deposited on the buffer layer and an exemplary TCO material may be a ZnO layer, an indium tin oxide (ITO) layer or a stack comprising both ZnO and ITO.

The conductive terminal 108 or conductive grid collects the current produced by the solar cell and is formed on a top surface 116 of the transparent layer 106. The conductive terminal 108 may include a plurality of conductive fingers 118 connected to a current collecting busbar 120. In this embodiment, the solar cell 100 may have a rectangular shape and the conductive fingers 118 may extend between a first edge 122 and a second edge 123 of the solar cell. The current collecting busbar 120 may extend along one of the edges, for example, the second edge 123 in a manner shown in FIG. 2B. Light, depicted with arrows ‘L’, enters the solar cell through exposed surface portions 117 of the top surface 116. The exposed surface portions 116A are portions of the surface that are not shadowed by the conductive terminal 108 and the other cell when the cells are interconnected in shingled manner.

As shown in FIGS. 2A and 2B, the components of the solar cell, i.e., the stacked layers 110, 112, 104, 106 and 108 extend between the first edge 122 and the second edge 123 of the solar cell 100 and are exposed at the edges of the solar cell. Such exposed edges are one of the challenges of the solar cells because when the solar cells are brought into close proximity to interconnect them for building solar modules, shorts may happen between the various components of the solar cells by way of such exposed edges or other exposed surfaces. The interconnection embodiments described below may minimize or eliminate such shorts between the cells in modules. According to these embodiments, the solar cells may be interconnected using a contact formed on the current collecting busbar of one of the solar cells and an insulation layer having at least one opening exposing at least a portion of the contact that is disposed over the solar cell before the substrate of the other solar cell is interconnected to the contact in shingled relationship.

FIGS. 3A-3C show exemplary insulation layers 130, 140 and 150 or separation layers. Each insulation layer may be made of module encapsulation material such as ethylene vinyl acetate copolymer (EVA), thermoplastic polyurethanes (TPU) and silicons, thermoplastic olefins (TPO), other thermoplastics or a similar insulation material or moisture barrier material with electrical insulation property. In general, any thermoplastic or thermoset polymers or their combinations may be used as insulation layers. The insulation layer 130 shown in FIG. 3A may include a peripheral wall 132 defining a number of openings such as opening 134, 135 136 and 137 to expose a contact (not shown). The insulation layer 140 shown in FIG. 3B has a peripheral wall 142, which is a continuous wall, defining an opening 144 to expose a contact. The insulation layer shown in FIG. 3C includes a discontinuous peripheral wall 152 having a first peripheral wall portion 154 and a second peripheral wall portion 156 defining an opening 158 or gap. Of course these embodiments show only a few of the possible insulation layers which can be used with the present invention. Other shapes, configurations and geometries may also be used with the present invention and they are within the scope of this invention. The insulation layers described above form a protective cushion between solar cells to mechanically separate them while electrically insulating them. The insulation layer may be made of single material layer, such as an encapsulant layer, or a multiple layers including encapsulants and other polymers compatible with encapsulants, such as a plastic layer sandwiched between the encapsulant layers.

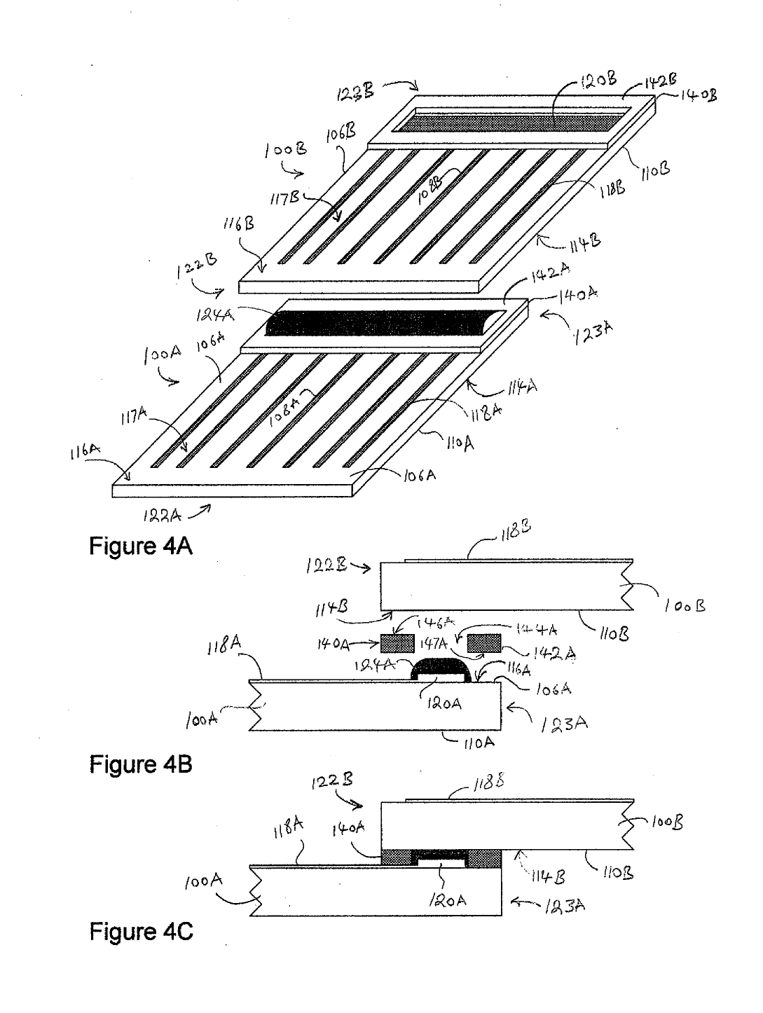

FIGS. 4A to 4C show various steps of an embodiment to interconnect a first solar cell 100A to a second solar cell 100B. The structures of the exemplary first and second solar cells, including the materials and the dimensions are the same as the solar cell 100 described in connection with FIGS. 2A-2B. However, for clarification purposes, to describe the parts of the solar cell 100A, a letter ‘A’ and to describe the parts of the solar cell 100B, a letter ‘B’ are added to each number used in the description of the parts of the solar cell 100 shown in FIGS. 2A-2B. Similarly, a letter ‘A’ and ‘B’ are added to the numbers used to describe the insulation layer 140 shown in FIG. 3B, when the insulation layer 140 is disposed over the solar cells 100A and 100B.

As shown in FIG. 4A in perspective view and in FIG. 4B in partial side view, a conductive material layer 124A or contact layer may be disposed over the current collecting busbar 120A disposed at a second edge 123A of the first solar cell 100A. Further, an insulation layer 140A is disposed over the current collecting busbar and around the conductive material layer 124A and over at least some of an exposed top surface 117A adjacent the second edge 123A. In this embodiment the conductive material layer 124A may preferably be a conductive adhesive or paste. The conductive material layer 124A is exposed through an opening 144A of the insulation layer 140A. A peripheral wall 142A of the insulation layer 140A surrounds the perimeter of the conductive material layer 124A, thereby electrically insulating it. Optionally, a top surface 146A and a bottom surface 147A of the peripheral wall 142A may have an adhesive on them to attach the insulation layer 140A to both solar cells when they are interconnected in a shingled relationship. The order of disposing the conductive material layer 124A and the insulation layer 140A may be reversed.

As shown in FIG. 4C in partial side view, to interconnect the second solar cell 100B with a conductive substrate 110B to the first solar cell 100A, a first edge 122B of a back surface 114B of the conductive substrate 110B is disposed on the conductive material layer 124A of the first solar cell 100A. In this configuration, the back surface 114B of the second solar cell 100B rests on the conductive material layer 124A and the insulation layer 140A on the first solar cell 100A. Because of the insulation layer 140A placed between them, the solar cells 100A and 100B can only contact through the conductive material layer 124A on the current collecting busbar 120A, thereby inhibiting any shorts between the solar cells 100A and 100B.

The conductive material layer 124A may be made of a flexible silver containing epoxy. Although the dimensions of the conductive material layer depend on the dielectric layer dimensions, it may be about 80-100 um thick and 6-8 mm wide. The conductive material layer including flexible silver containing epoxy may be cured around 120-180° C. for 5 seconds to 10 minutes. Insulation layer dimensions depend on the dimensions of the overlap area of the solar cells and the cell. In one implementation, it is preferred to cover the whole overlap area between cells and extend out of this area about 5-15% more so that there is sufficient insulation between the cells. The insulation layer may or may not need to have an adhesive on it. When encapsulants are used as insulation layers the insulation layers more easily adhere to the solar module or solar cell materials as they melt during the module lamination process stage due to their low melting point.

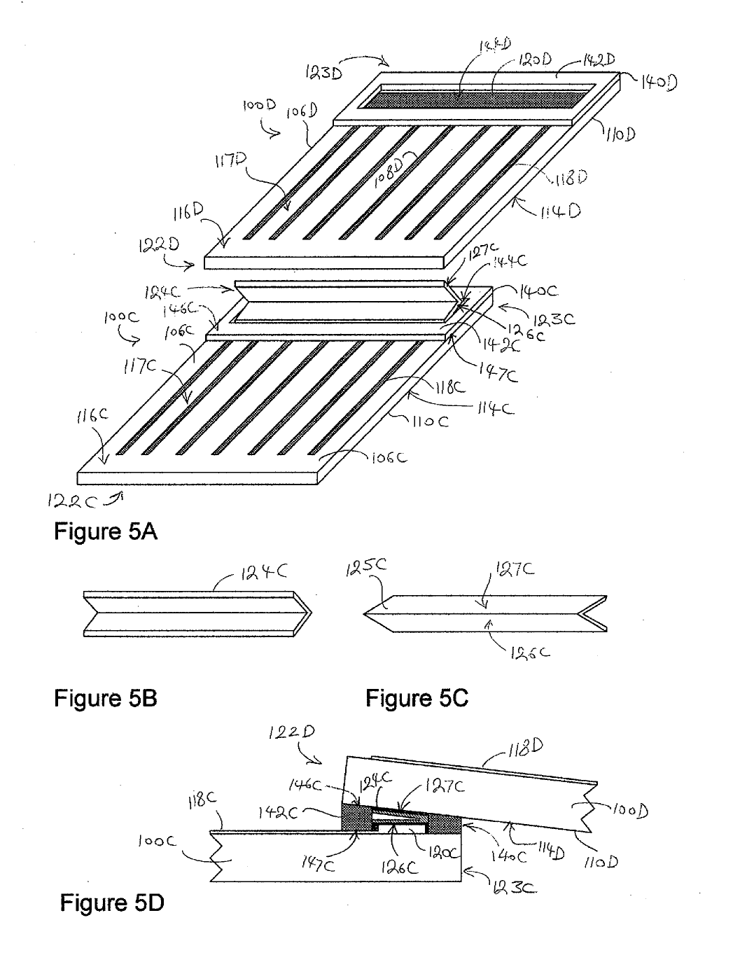

FIGS. 5A and 5C show various steps of another embodiment to interconnect a first solar cell 100C to a second solar cell 100D. The structures of the exemplary first and the second solar cells, including the materials and the dimensions are the same as the solar cell 100 described in connection with FIGS. 2A-2B. However, for clarification purposes, to describe the parts of the solar cell 100C, a letter ‘C’ and to describe the parts of the solar cell 100D, a letter ‘D’ are added to each number used in the description of the parts of the solar cell 100 shown in FIGS. 2A-2B. Similarly, a letter ‘C’ and ‘D’ are added to the numbers used to describe the insulation layer 140 shown in FIG. 3B, when the insulation layer 140 is disposed over the solar cells 100C and 100D.

As shown in FIG. 5A in perspective view and in FIG. 5D in partial side view, a conductive foil 124C or contact may be attached to the current collecting busbar 120C disposed at a second edge 123C of the first solar cell 100C. An insulation layer 140C is disposed over the current collecting busbar 120C and around the conductive foil 124C. The insulation layer 140C may cover at least some of an exposed top surface 117C adjacent the second edge 123C of the first solar cell 100C.

As shown in FIG. 5B in front view and in FIG. 5C in back view, in this embodiment, the conductive foil 124C may be a rectangular sheet which is folded into a V-shape as in the manner shown in the figures. In the folded configuration, a back surface 125C of the conductive foil 124C may have a first surface 126C and a second surface 127C. The first and the second surfaces 126C and 127C may have an equal size and shape and be coated with a conductive adhesive. As shown in FIG. 5A, the first surface 126C of the conductive foil 124C is attached to the current collecting busbar 120C of the first solar cell and is exposed through an opening 144C of the insulation layer 140C. A peripheral wall 142C of the insulation layer 140C surrounds the perimeter of the conductive foil 124C, thereby electrically insulating it. A top surface 146C and a bottom surface 147C of the peripheral wall 142C may optionally include an adhesive film on them to attach the insulation layer 140C to both solar cells when they are in a shingled relationship. The order of attaching the conductive foil 124C and the insulation layer 140C may be reversed.

As shown in FIG. 5D in partial side view, in the following step, to interconnect the second solar cell 100D with a conductive substrate 110D to the first solar cell 100C, a first edge 122D of a back surface 114D of the conductive substrate 110D is disposed on the first surface 127C of the conductive foil 124C on the first solar cell 100C. In this configuration, the back surface 114D of the second solar cell 100D is attached to both the second surface 127C of the conductive foil 124C and the insulation layer 140C on the first solar cell 100C. The insulation layer 140C separates the solar cells and inhibits any shorts between them. Another advantage of this interconnection scheme may be the hinged interconnection formed between the solar cells 100C and 100D, which adds more flexibility to the module formed by such interconnected solar cells. This additional flexibility is especially needed when the modules including such interconnected solar cells are covered over surfaces, such as rooftops or walls, with complex geometries for esthetical, design or technical purposes. The conductive foil may be a copper ribbon with or without a protective coating of aluminum. Conductive ribbons including gold or silver may also be used. Thickness, width and length of the conductive foil are constrained by the cell design and conductivity requirements. Conductive ribbons can be acquired with or without an adhesive layer on them. The adhesive layer can be a pressure sensitive layer or a thermally activated layer as well as a UV curable layer.

Both the flexible epoxy forming the conductive material layer 124A and the folded conductive foil 124C are configured so as to be biased outwards. The interconnection between the shingled cells compresses both embodiments of the contact which results in the contact being biased outward. This results in electrical contact being more reliably maintained between the cells via either the conductive material layer 124A or the conductive foil 124C through relative movements of the cells which can occur in rooftop applications that are exposed to wind, building movement and the like.

Although aspects and advantages of the present inventions are described herein with respect to certain preferred embodiments, modifications of the preferred embodiments will be apparent to those skilled in the art. Thus, the scope of the present invention should not be limited to the foregoing description, but should be defined by the appended claims.

What is claimed is:

1. A method of serially interconnecting first and second solar cells in a shingled manner, wherein each solar cell includes an absorber layer interposed between a conductive substrate and a transparent layer having a top surface on which a conductive terminal including conductive fingers connected to a current collecting busbar is disposed, the method comprising:
forming at least one contact on the current collecting busbar disposed over an edge portion of the first solar cell;
disposing an electrically insulating layer over the current collecting busbar and at least a portion of the top surface of the transparent layer, the electrically insulating layer at least partially exposing the at least one contact; and
arranging the first and second cells in a shingled relationship so as to connect a selected area of a portion of the conductive substrate of the second solar cell to the at least one contact on the conductive terminal of the first solar cell to establish a continuous electrical connection between the terminal of the first solar cell and the substrate of the second solar cell while the portion of the conductive substrate of the second cell is resting on the electrically insulating layer that is at least partially exposing the at least one contact to inhibit short circuits between the conductive substrate of the second solar cell and the edge portion of the first solar cell.

2. The method of claim 1 further comprising applying an adhesive to the electrically insulating layer before the step of forming the electrically insulating layer.

3. The method of claim 1, wherein the contact is formed so as to be biased outward to more reliably maintain electrical contact between the first and second cells during relative movement between the first and second cells.

4. The method of claim 3, wherein the at least one contact is made of a conductive adhesive.

5. The method of claim 3, wherein the at least one contact is made of a conductive foil having a first surface and a second surface.

6. The method of claim 5, wherein the conductive foil is folded so as to attach a first surface portion of the first surface to the current collecting busbar of the first solar cell and a second surface portion of the first surface to the selected area of the conductive substrate of the second solar cell.

7. The method of claim 6 further comprising applying an adhesive to the first surface portion and the second surface portion.

8. The method of claim 1, wherein the electrically insulating layer is one of EVA, TPU, TPO or silicon material.

9. The method of claim 5, wherein the conductive foil comprises copper.

10. The method of claim 1, wherein the electrically insulating layer includes an opening and a peripheral edge section to surround the at least one contact.

11. The method of claim 1, wherein the electrically insulating layer includes a plurality of openings exposing a plurality of portions of the at least one contact.

12. The method of claim 1, wherein the electrically insulating layer is a discontinuous layer having a first elongated section disposed along a first elongated edge of the current collecting busbar and a second elongated section disposed along a second elongated edge of the current collecting busbar, wherein the at least one contact is exposed between the first elongated section and the second elongated section.

13. The method of claim 1, wherein the absorber layer is a Group IBIIIAVIA compound thin film.

14. The method of claim 1, wherein the conductive substrate includes one of stainless steel foil and aluminum foil.

15. The method of claim 1, wherein the transparent layer includes CdS and ZnO films.

16. A solar cell assembly comprising:
a first solar cell which includes a conductive substrate and a transparent layer with an absorber layer interposed therebetween, wherein the transparent layer defines an upper surface and wherein a conductive terminal is formed on the upper surface of the transparent layer;
at least one contact formed so as to be electrically connected to the conductive terminal of the first solar cell;
an insulator that is positioned on the upper surface of the first solar cell, wherein the insulator defines an opening that provides access to the at least one contact;
a second solar cell which includes a conductive substrate wherein the second solar cell is positioned so that the conductive substrate is positioned over the opening in the insulator in the first solar cell so that the conductive substrate of the second solar cell is in physical and electrical contact with the at least one contact and wherein the insulator provides electrical insulation between the conductive substrate of the second solar cell and the first solar cell to inhibit short circuits therebetween.

17. The assembly of claim 16, wherein the first and second solar cells are shingled together.

18. The assembly of claim 16, wherein the conductive terminal comprises a plurality of conductive fingers that are interconnected by a conductive busbar.

19. The assembly of claim 18, wherein the transparent layer has a first and a second edge and the at least one contact is formed adjacent the first edge of the transparent layer.

20. The assembly of claim 19, wherein the at least one contact is formed on the conductive busbar.

21. The assembly of claim 16, wherein the at least one contact is formed so as to be biased outward to more reliably maintain electrical contact between the first and second cells during relative movement between the first and second cells.

22. The assembly of claim 21, wherein the at least one contact is formed of a conductive adhesive.

23. The assembly of claim 21, wherein the at least one contact is made of a conductive foil having a first surface and a second surface.

24. The assembly of claim 23, wherein the conductive foil is folded so as to attach a first surface portion of the conductive foil to the at least one contact of the first solar cell and a second surface portion to the conductive substrate of the second cell.

25. The assembly of claim 24, wherein the conductive foil comprises a copper foil.

26. The assembly of claim 16, wherein the electrically insulating layer includes an opening and a peripheral edge section to surround the at least one contact.

27. The assembly of claim 16, wherein the electrically insulating layer includes a plurality of openings exposing a plurality of portions of the at least one contact.

28. The assembly of claim 16, wherein the electrically insulating layer is a discontinuous layer having a first elongated section disposed along a first elongated edge of the current collecting busbar and a second elongated section disposed along a second elongated edge of the current collecting busbar, wherein the at last one contact is exposed between the first elongated section and the second elongated section.

29. The assembly of claim 16, wherein the absorber layer is a Group IBIIIAVIA compound thin film.

30. The assembly of claim 16, wherein the conductive substrate includes one of stainless steel foil and aluminum foil.

31. The assembly of claim 16, wherein the transparent layer includes CdS and ZnO films.

32. The assembly of claim 15, wherein the electrically insulating layer is made of a film stack including a plurality of insulating films.

33. The assembly of claim 30, wherein the plurality of insulating films include a top insulating film a bottom insulating film and an intermediate insulating film, wherein the intermediate insulating film is different from the top and bottom insulating films.

34. A solar cell assembly comprising:
at least a first solar cell that includes a transparent layer on a first surface with a conductive terminal formed on the first surface;
a contact that is formed on the first surface of the first solar cell and is electrically connected to the conductive terminal of the first solar cell;
an insulator formed on the first surface of the first solar cell that defines an opening wherein the contact is accessed via the opening; and
a second solar cell that has a first surface and a conductive second surface wherein the conductive second surface is positioned on the insulator so that the insulator insulates the conductive second surface from the first surface of the first solar cell and so that the second conductive surface of the second solar cell is electrically connected to the first solar cell via the contact that is exposed in the opening of the insulator.
